(19) United States
(12) Patent Application Publication
(10) Pub. No.: US 2025/0233017 A1
(43) Pub. Date: Jul. 17, 2025

(54) GAP-FILLING METHOD FOR A SEMICONDUCTOR DEVICE AND METHOD OF MANUFACTURING A SEMICONDUCTOR DEVICE USING THE SAME

(71) Applicant: WONIK IPS CO., LTD., Pyeongtaek-si Gyeonggi-do (KR)

(72) Inventors: Chang Gyu SONG, Pyeongtaek-si Gyeonggi-do (KR); Ye Ji CHOI, Pyeongtaek-si Gyeonggi-do (KR); Sang Min LEE, Pyeongtaek-si Gyeonggi-do (KR); Young Chul CHOI, Pyeongtaek-si Gyeonggi-do (KR); Min Ji KIM, Pyeongtaek-si Gyeonggi-do (KR)

(73) Assignee: WONIK IPS CO., LTD., Pyeongtaek-si Gyeonggi-do (KR)

(21) Appl. No.: 18/942,030

(22) Filed: Nov. 8, 2024

(30) Foreign Application Priority Data
Jan. 16, 2024 (KR) 10-2024-0006743

(51) Int. Cl. H01L 21/768; C23C 16/509; C23C 16/513; H01J 37/32; H01L 21/02

(52) U.S. Cl. CPC H01L 21/76837; C23C 16/509; C23C 16/513; H01J 37/32146; H01J 37/32165; H01L 21/0217; H01L 21/02211; H01L 21/02274; H01L 21/76898; H01J 2237/3321

(57) ABSTRACT

A gap-filling method for a semiconductor device and method of manufacturing the semiconductor device using the same, are provided. The gap-filling method may include: preparing a substrate with a hole pattern; supplying a process gas to the substrate and applying a first VHF power source to form a pulse wave plasma to form a first silicon nitride layer in the hole pattern; and supplying the process gas to the substrate and applying a second VHF power source to form a continuous wave plasma to form a second silicon nitride layer on the first silicon nitride layer.

### CROSS-REFERENCES TO RELATED APPLICATION

The present application claims priority under 35 U.S.C. § 119(a) to Korean patent application number 10-2024-0006743, filed on Jan. 16, 2024, in the Korean Intellectual Property Office, which application is incorporated herein by reference in its entirety.

### BACKGROUND

### 1. Technical Field

Example embodiments relate to a gap-filling method for a semiconductor device and a method of manufacturing a semiconductor device using the same.

### 2. Related Art

As an integration density of a semiconductor device has been improved, a width of each of conductive patterns and a gap between the conductive patterns which are adjacent of the semiconductor device may have become progressively finer. In particular, in recent years, the semiconductor devices with a back side power delivery network (BSPDN) structure have been attracting attention to solve problems such as bottlenecks caused by semiconductor devices with a front side power delivery network (FSPDN) structure, which are arranged in an order of power lines, signal lines and transistors. The BSPDN structure may be expected to improve power efficiency and enhance a performance of chips by placing power supply lines on the back side of a wafer in the semiconductor devices gradually being miniaturized.

For example, the semiconductor devices with the BSPDN structures may require a gap-filling process of silicon nitride layers for an alignment of through silicon via (TSV) electrodes. When an atomic layer deposition (ALD) process may be used to deposit the silicon nitride layer and gap-fill it into a fine-sized hole, a time required for gap-filling may be greatly increased. Further, seams may be generated in the thin layer in the fine-sized hole. In addition, when a chemical vapor deposition (CVD) process may be used to deposit the silicon nitride layer and gap-fill the fine-sized hole, a void may be easily generated in the thin layer in the fine-sized hole.

Conventionally, in order to perform a process for gap-filling the fine-sized hole with the silicon nitride, a first silicon nitride layer may be deposited over an even surface of a substrate, by the ALD process to a first thickness. Then, a second silicon nitride layer may be deposited on the first silicon nitride layer by the CVD process to a second thickness, to generate an overburden. The substrate on which the second silicon nitride layer with the overburden (OL) may be formed may be planarized by a chemical mechanical polishing (CMP) process.

However, since the conventional method requires two process steps including the ALD process and the CVD process for the gap filling in the fine-sized hole, process time increases, the gap-fill process become more complex, and a productivity of the semiconductor device decreases.

### SUMMARY

According to example embodiments, there may be provided a gap-fill method for a semiconductor device. The gap-filling method may be processed in a substrate processing apparatus. A substrate with a hole pattern may be prepared. A process gas may be supplied to the substrate. A first VHF power may be applied the process gas to form a pulsed wave plasma, thereby forming a first silicon nitride layer on the pattern. The process gas may then be supplied to the substrate. A second VHF power may be applied to the process gas to form a continuous wave plasma, thereby forming a second silicon nitride layer on the first silicon nitride layer.

According to example embodiments, there may be provided a method of manufacturing a semiconductor device. A substrate with a trench may be prepared. A first layer may be formed under a pulse wave plasma atmosphere, to fill the trench. A second layer may be formed on the first layer under a continuous wave plasma atmosphere, thereby applying an overburden to the first layer. The first and the second layers is planarized using a chemical mechanical polishing, to form a gap-filled layer in the trench.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a flow chart for illustrating a gap-filling method for a semiconductor device in accordance with example embodiments;

FIGS. 2A to 2D are cross-sectional views of a semiconductor substrate for illustrating method of forming a gap-filled layer of a semiconductor device in accordance with example embodiments;

FIG. 3 is a cross-sectional view illustrating a substrate processing apparatus for forming a gap-filled layer of a semiconductor device in accordance with example embodiments;

FIG. 4 is a flow chart illustrating a method of manufacturing a semiconductor device in accordance with example embodiments;

FIG. 5A is a cross-sectional view showing a gap-filled layer in accordance with an example 1; and

FIGS. 5B and 5C are cross-sectional views showing gap-filled layers in accordance with examples 2 and 3.

### DETAILED DESCRIPTION

The advantages and features of the present disclosure, and methods of achieving them, will become apparent upon reference to the embodiments described in detail with reference to the accompanying drawings. The disclosure, however, is not limited to the embodiments disclosed herein, but will be embodied in many different forms, and these embodiments are provided merely to make the disclosure of the disclosure complete, and to give those having ordinary skill in the art to which the disclosure belongs a complete idea of the scope of the disclosure, which is defined by the claims. The dimensions and relative sizes of the layers and regions in the drawings may be exaggerated for clarity of description. Throughout the specification, like reference numerals refer to like components.

Example embodiments may provide a gap-filling method for a semiconductor device that may be capable of filling a gap between patterns in a short time through an in-situ process using a CVD process.

According to example embodiments, the gap-fill method of the semiconductor device may use then in-situ process in which a first silicon nitride layer may be deposited on the pattern by forming the pulsed wave plasma, and a second silicon nitride layer may be deposited on the first silicon nitride layer by forming the continuous wave plasma to gap-fill the pattern having the aspect ratio in a short time on a single process equipment, thereby improving productivity, and preventing the generations of defects such as seams, voids, and the like. As a result, the semiconductor devices with excellent electrical properties may be manufactured.

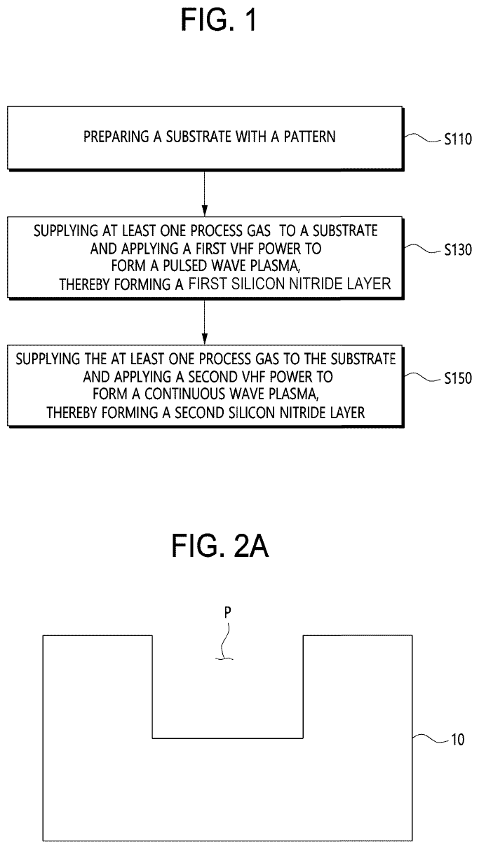

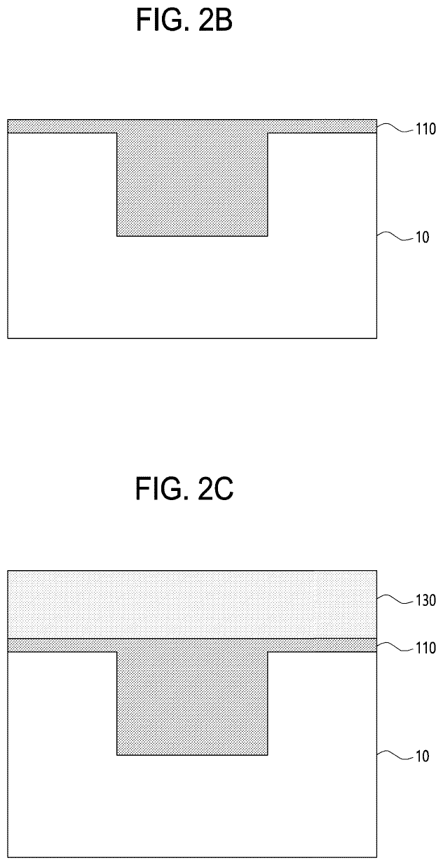

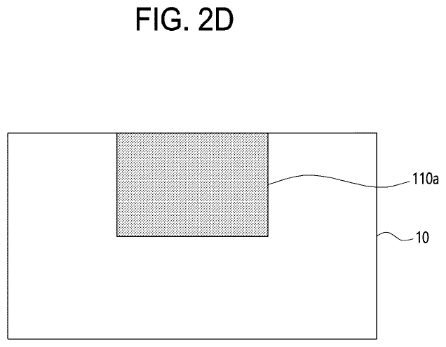

FIG. 1 is a flow chart for illustrating a gap-filling method for a semiconductor device in accordance with example embodiments. FIGS. 2A to 2D are cross-sectional views of a semiconductor substrate for illustrating method of forming a gap-filled layer of a semiconductor device in accordance with example embodiments.

Referring to FIG. 1, a gap-filling method for semiconductor device in accordance with example embodiments may include preparing a substrate 10 on which a pattern may be formed (S110); supplying at least one process gas, and applying a first VHF power toe the process gas to form a pulsed wave plasma, thereby forming a first silicon nitride layer 110 on a surface of the pattern (S130); and supplying the at least one process gas, and applying a second VHF power to the process gas to form a continuous wave plasma, thereby forming a second silicon nitride layer 130 on a surface of the first silicon nitride layer 110 (S150).

The gap-fill method for the semiconductor device in accordance with example embodiments may be performed using a substrate processing apparatus 200. The substrate processing apparatus 200 will be described in more detail below.

Referring to FIGS. 1 and 2A, a substrate 10 may be prepared (S110). A plurality of patterns (P) may be formed in one surface of the substrate 10. The plurality of patterns may be formed by etching the substrate 10. For example, at least one of the patterns P may be a hole pattern, such as a trench. Accordingly, the upper surface of the substrate 10 may be uneven. For example, the hole pattern P may have an aspect ratio of 0.1 to 1. Further, a diameter (or critical dimension: CD) of the hole pattern P may be 10 nm to 1,000 nm, preferably, 40 nm to 500 nm.

As an exemplary embodiment, the plurality of patterns P may be formed over the one surface of the substrate 10. Further, the plurality of patterns P may include a conductive material or an insulating material.

For example, the substrate 10 may include silicon, silicon oxide, strained silicon, silicon on insulator (SOI), carbon doped silicon oxide, amorphous silicon, doped silicon, a semiconductor material such as germanium, gallium, arsenic, glass, sapphire, and any other material, such as metal, metal nitride, metal alloy, and other conductive materials.

Referring to FIGS. 1 and 2B, a first silicon nitride layer 110 may be formed on the substrate 10, by supplying the at least one process gas (S130). For example, the first silicon nitride layer 110 may be one of insulating layers for gap-filling the hole pattern P. A first VHF (very high frequency) power may be properly applied to a shower head (not shown) that injects the process gas to form a pulsed wave plasma in a process chamber (not shown), when the first silicon nitride layer 110 is formed.

For example, the process gas may include a silicon source gas and a nitrogen-including gas.

The silicon source gas may include a SixHy-based silicon precursor, an organic silicon precursor compound, an alkyl silane, an amino silane, or compounds thereof.

For example, the Si_{X}H_{Y}-based silicon precursors may include, for example, monosilane (SiH₄), disilane (Si₂H₆), trisilane (Si₃H₈), tetrasilane (Si₄H₁₀), isotetrasilane, neopentasilane (Si₅H₁₂), cyclopentasilane (Si₅H₁₀), hexasilane (C₆H₁₄), cyclohexasilane (Si₆H₁₂), or compounds thereof.

For example, the organic silicon precursor compound may be selected from tetraethylorthosilicate (TEOS), dichlorosilane, dimethyldimethoxysilane, silicon tetrachloride, silicon tetrachloride, bis(tertiary-butylamino) silane, dicholrosilane, 1,3,5,7-tetramethylcyclotetrasiloxane, and octamethyl cyclotetrasiloxanes, tris(tert-pentoxy)silanol, hexamethyldisilazane, tetrakis (dimethylamino) silicon, tetramethylsilane, tetramethyldisiloxane, and tetramethyldisiloxane, diethylsilane, hexachlorodisilane, diethoxydimethylsilane, polydimethylsiloxane, or compounds thereof, may be exemplary.

The alkyl silanes may include methylsilane, dimethylsilane,

trimethylsilane, tetramethylsilane, ethylsilane, diethylsilane, tetraethylsilane, propylsilane, dipropylsilane, isobutylsilane, tert-tert-butylsilane, dibutylsilane, methylethylsilane, dimethyldiethylsilane, methyltriethylsilane, ethyltrimethylsilane, isopropylsilane, diisopropylsilane, triisopropylsilane, or mixtures thereof, may be exemplary.

The amino silanes may include diisopropylaminosilane (DIPAS), bisdiethylaminosilane (BDEAS), butylaminosilane (BAS), bistort-butylaminosilane (BTBAS), dimethylaminosilane (DMAS), bisdimethylaminosilane (BDMAS), trisdimethylaminosilane (TDMAS), diethylaminosilane (DEAS), dipropylaminosilane (DPAS), diisopropylaminosilane (DIPAS), or mixtures thereof, may be representative examples.

The nitrogen-including gas may include at least one of nitrogen (N₂) gas, nitrogen dioxide (NO₂) gas, nitrous oxide (N₂O) gas, nitrogen monoxide (NO) gas, ammonia (NH₃) gas, and amine (R—NH₂) gas.

For example, the first VHF power may be applied in the form of pulsed waves to form the pulsed wave plasma in the process chamber.

The first VHF power may have a frequency range of about 20 MHz to about 70 MHz. For example, the first VHF power may have a frequency of about 27.12 MHz.

The pulsed wave plasma may be formed by applying the first VHF power having a predetermined duty ratio with repeated on/off cycles at regular time intervals.

For example, the duty ratio may be 20% to 80%. In particular, the pulsed wave plasma for forming the first silicon nitride layer may be formed by applying a first VHF power having a duty ratio of about 40% to about 60%, preferably a duty ratio of about 50%.

The pulsed wave plasma may activate the at least one process gas to form a plurality of radicals. A separation distance between the radicals activated by the pulsed wave plasma may increase, compared to a separation distance between radicals activated by a continuous wave plasma. As the separation distance of the radicals increases, a diffusion length of the radicals increases. Thus, the hole pattern P with the high aspect ratio may be filled by the first silicon nitride layer 110.

Further, the first VHF power may increase a deposition rate on a bottom portion of the hole pattern P compared to a LF (low frequency) power and a HF (high frequency) power. As the deposition rate of the bottom portion of the hole pattern P is improved, a seam or a void defect in the first silicon nitride layer 110 filled within the hole pattern P are reduced.

Referring to FIGS. 1 and 2C, a second silicon nitride layer 130 may be formed on the first silicon nitride layer 110, by supplying the at least one process (S150). For example, a second VHF power may be applied to the shower head, to form a continuous wave plasma.

Since the second silicon nitride layer 130 is formed by the continuous wave plasma, the second silicon nitride layer 130 may be quickly formed.

In an exemplary embodiment, the second VHF power may have a frequency range of about 20 MHz to about 70 MHz. For example, the second VHF power may be identical with the first VHF power. Alternately, the second VHF power may be different from the first VHF power. For example, the second VHF power may have a frequency of about 27.12 MHz.

At least one process gas of the first silicon nitride layer 110 may be identical with at least one process gas of the second silicon nitride layer 130. Alternately, at least one process gas of the first silicon nitride layer 110 may be different from at least one process gas of the second silicon nitride layer 130.

For example, a thickness of the first silicon nitride layer 110 may be different from a thickness of the second silicon nitride layer 130. In an exemplary embodiment, the thickness of the second silicon nitride layer 130 may be thicker than the thickness of the first silicon nitride layer 110.

Referring to FIGS. 1 and 2D, the second and first silicon nitride layers 110 and 130 may be polished by a chemical mechanical polishing (CMP) process to be exposed the one surface of the substrate 10. Accordingly, a gap-filled layer 110a that fills an inside of the hole pattern P is formed. The substrate 10 and the gap-filled layer 110a may be planarized by the CMP process.

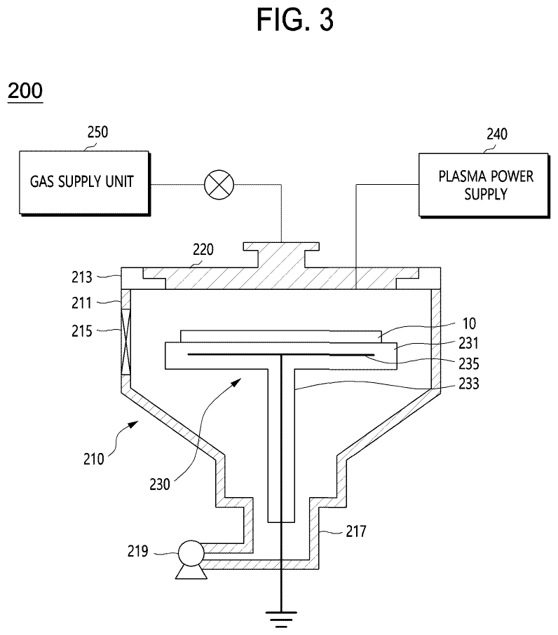

FIG. 3 is a cross-sectional view illustrating a substrate processing apparatus for forming a gap-filled layer of a semiconductor device in accordance with example embodiments.

Referring to FIG. 3, a substrate processing apparatus 200 for forming a gap-filled layer may include a process chamber 210, a shower head 220, a substrate supporting unit 230 and a plasma power supply 240.

First, the process chamber 210 may include a chamber body 211 with an open top and a top lid 213 installed on a top periphery of the chamber body 211. An inner space of the top lid 213 may be closed by the shower head 220 to form a process space. The process space may provide a space for processing of the substrate 10, such as a deposition process.

The chamber body 211 may include a gate 215 for loading and unloading the substrate 10 at designated locations on a sidewall of the chamber body 211. Further, the substrate processing chamber 200 may include at least one pump 219 and at least one vent 217. For example, the pump 219 may be connected to the exhaust vent 217 located at the bottom of the process chamber 210.

The shower head 220 may be installed on the inside of the

top lid 213 opposite the substrate supporting unit 230. The shower head 220 may receive various process gases supplied from a gas supply unit 250. The shower head 220 injects the process gases into the process chamber 210. The shower head 220 may act as a first electrode for generating plasma.

The gas supply unit 250 may provide a source gas, a purge gas, a reaction gas, a carrier gas, or the like. The shower head 220 may inject the gases into the process chamber 210.

The substrate supporting unit 230 may serve to support the substrate 10 in the process space. The substrate supporting unit 230 may include a susceptor 231 and a support shaft 233. The susceptor 231 may have an overall flat plate shape configured to receive at least one substrate 10. The support shaft 233 may be vertically combined with a rear surface of the susceptor 231. The support shaft 233 may be externally connected to a driving member (not shown) through a hole (not shown) in the bottom of the process chamber 210 to lift and rotate the susceptor 231 in both directions.

Further, the susceptor 231 may act as a second electrode for generating plasma, thereby forming plasma under the substrate 10 to form a structure that allows ions to migrate in a straight line over the patterns P (See FIGS. 2A to 2D) on the substrate 10. Further, the susceptor 231 may be provided with a second electrode. The shower head 220 may be electrically connected to one of the plasma power supply 240 and a ground terminal. The susceptor 231 may be electrically connected to the other one of the plasma power supply 240 and the ground terminal.

Furthermore, a heater 235 may be provided in the susceptor 231. The heater 235 may be connected to a separate power source to regulate a temperature of the substrate 10 mounted on the susceptor 231.

The plasma power supply 240 may be connected to the shower head 220 or the susceptor 231 of the substrate supporting unit 230 to provide a very high frequency (VHF) power with a central frequency band of about 20 MHz to about 70 MHz as a plasma power source. The plasma power supply 240 may provide the VHF power in the continuous wave form and the pulsed wave form, respectively.

The gas supply unit 250 may serve to supply the process gas, the inert gas, the purge gas, or the like to the shower head 220 for performing the process for processing the substrate 10. The gas supply unit 250 may be connected to the shower head 220 by at least one gas line (not shown).

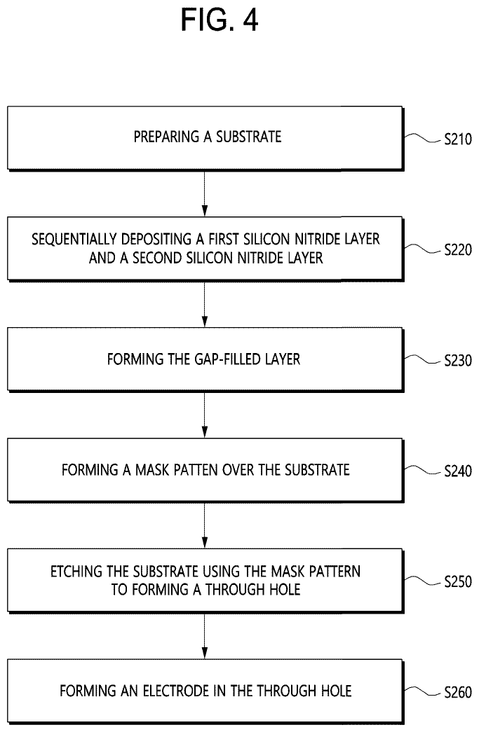

FIG. 4 is a flow chart illustrating a method of manufacturing a semiconductor device in accordance with example embodiments.

Referring to FIGS. 2A to 2D, 3 and 4, a substrate 10 having at least one hole pattern P is prepared (S210). For example, the hole pattern P may be formed in the substrate 10. Alternately, the hole pattern P may also be formed in at least one layer formed on a surface of the substrate 10. The substrate 10 may be loaded into the process space of the process chamber 210 through the gate 215.

A first silicon nitride layer 110 and a second silicon nitride layer 130 are sequentially deposited on the substrate 10, by changing process conditions (S220).

For example, the first silicon nitride layer 110 may be deposited to gap-fill the hole pattern P using a pulsed wave plasma. The second silicon nitride layer 130 may be deposited on the first silicon nitride layer 110 using a continuous wave plasma, to act as an overburden layer. For example, since the second silicon nitride layer 130 is the overburden layer, the first silicon nitride layer 110 becomes denser. Thus, the first silicon nitride layer 110 without seams or voids is filled within the hole pattern P.

The first silicon nitride layer 110 and the second silicon nitride layer 130 may be planarized by a CMP process to expose the upper surface of the substrate to form a gap-filled layer 110a (S230) with a planarized surface.

Alternately, a mask pattern (not shown) may be formed over the substrate 10 with the gap-filled layer 110a (S240). For example, before forming the mask pattern, at least one layer may be formed on the substrate 10 with the gap-filled layer 110a and the mask pattern is formed on the at least one layer (not shown). The at least one layer may include an insulating layer, such as, a silicon oxide layer.

The substrate 10 including the at least one layer (not shown) and the gap-filled layer 110a may be etched by the mask patten to a through hole (not shown) (S250).

Then, an electrode may be formed to fill the through hole (S260). For example, the electrode may include a TSV (through silicon via).

According to example embodiments, in the gap-filling method for the semiconductor device, the first silicon nitride layer 110 may be deposited on the surface of the pattern by forming the pulsed wave plasma, by using then in-situ process for forming the continuous wave plasma to deposit the second silicon nitride layer 130 on the upper surface of the first silicon nitride layer 110. Thus, it may be possible to gap-fill the hole pattern using a substrate processing apparatus, thereby improving productivity and preventing the occurrence of defects such as seams, voids, and the like, thereby manufacturing semiconductor devices with excellent electrical properties.

In particular, in the conventional method of gap-filling the

pattern with a silicon nitride layer using an atomic layer deposition method and forming an overburden layer using a chemical vapor deposition method, the process time may be about 30 minutes or more. By utilizing the gap-filling method for the semiconductor device in accordance with example embodiments, the process time may be reduced to less than about 10 minutes, which is expected to have a significant productivity improvement effect.

Example embodiments will now be described in more detail by way of example.

Example embodiments shown may be only specific examples of the disclosure and are not intended to limit the technical scope of the disclosure.

### Example 1

A substrate with a plurality of patterns having a width of 61.9 nm and a height of 82.5 nm were prepared. The substrate was loaded into a process chamber.

A silane (SiH₄) gas and a nitrogen (N₂) gas are supplied as process gases, respectively. A VHF power with a frequency of 27.12 MHz and a duty of 50% is applied in a pulse wave type, to form a pulse wave plasma in the process chamber. A first silicon nitride layer is formed to be filled in the hole pattern by a PECVD (plasma enhanced chemical vapor deposition).

Then, the silane (SiH₄) gas and the nitrogen (N₂) gas are supplied as the process gases, respectively. The VHF power with the frequency of 27.12 MHz is applied in a continuous wave type, to form a continuous wave plasma in the process chamber. A second silicon nitride layer is formed in the form of an overburden on the surface of the first silicon nitride layer by PECVD.

### Example 2

A substrate with a plurality of patterns having a width of 48.8 nm and a height of 53.7 nm were prepared. The substrate was loaded into a process chamber.

A silane (SiH4) gas and a nitrogen (N2) gas were supplied as process gases, respectively, and an HF power with a frequency of 13.56 MHz and a duty of 50% was applied to form a pulse wave plasma to deposit a first silicon nitride layer on a surface of the pattern by the PECVD method to gap-fill a part of the pattern.

Then, a silane (SiH4) gas and a nitrogen (N2) gas were supplied as process gases, respectively, and a continuous wave plasma was formed by applying an HF power of 13.56 MHz to form a continuous wave plasma to deposit a second silicon nitride layer in the form of an overburden on the surface of the first silicon nitride layer by the PECVD method.

### Example 3

A substrate with a plurality of pattern having a width of 33.8 nm and a height of 45.0 nm were prepared. The substrate was loaded into a process chamber.

A silane (SiH4) gas and a nitrogen (N2) gas were supplied as process gases, respectively, and an HF power with a frequency of 13.56 MHz was applied to form a continuous wave plasma to gap-fill the above pattern and form an overburdened silicon nitride layer by the PECVD method.

### Comparison Between the Examples 1 to 3

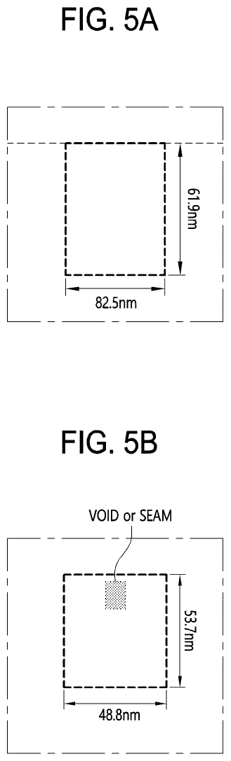

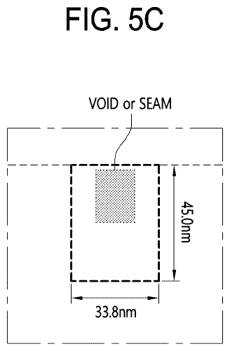

FIG. 5A is a SEM image showing the gap-filled layer in accordance with the example 1, and FIGS. 5B and 5C are SEM images showing the gap-filled layers in accordance with the examples 2 and 3.

As shown in FIG. 5A, in a gap-filled sample in which the first silicon nitride layer was formed with the pulsed wave plasma and the second silicon nitride layer was formed with the continuous wave plasma in accordance with example embodiments, in may be noted that no defects such as voids or seams were identified in the gap-filled silicon nitride layer in the pattern.

On the other hand, as shown in FIG. 5B and FIG. 5C, in both of gap-filled samples formed by the example 2 and the example 3, it may be noted that voids were formed in the gap-filled silicon nitride layer in the hole pattern. In particular, compared to the case of forming the continuous wave plasma by applying HF power as in the example 3, a size of the defect was significantly reduced when the first silicon nitride layer was deposited by forming the pulsed plasma by applying HF power as in the example 2 and then the second silicon nitride layer was deposited by forming the continuous wave plasma, confirming that the gap-fill properties can be improved by utilizing a pulsed plasma.

What is claimed is:

1. A gap-filing method for a semiconductor device using a substrate processing apparatus, the substrate processing apparatus comprising a process chamber having a process space, a substrate supporting unit located in the process space and on which a substrate is supported, a shower head located over the substrate supporting unit to inject at least one process gas into the substrate, and a plasma power supply configured to supply power to at least one of the substrate supporting unit and the shower head, the gap-filling method comprising:
preparing a substrate with a hole pattern;
supplying the at least one process gas to the substrate;
applying a first VHF power to the process gas to form a pulsed wave plasma in the process chamber, thereby forming a first silicon nitride layer to fill the hole pattern;
supplying the at least one process gas to the substrate; and
applying a second VHF power to the process gas to form a continuous wave plasma, thereby forming a second silicon nitride layer on the first silicon nitride layer.

2. The gap-filling method of claim 1, wherein a thickness of the first silicon nitride layer is different from a thickness of the second silicon nitride layer.

3. The gap-filling method of claim 2, wherein the thickness of the first silicon nitride layer is thinner than the thickness of the second silicon nitride layer.

4. The gap-filling method of claim 1, wherein the pulsed wave plasma has a duty ratio of about 20% to about 80%.

5. The gap-filling method of claim 1, wherein at least one of the first VHF power and the second VHF power source has a frequency of about 27.12 MHz.

6. The gap-filling method of claim 1, wherein a frequency of the first VHF power source is different from a frequency of the second VHF power source.

7. The gap-filling method of claim 1, wherein a diameter of the hole pattern is 10 nm to 1,000 nm.

8. The gap-filling method of claim 1, wherein an aspect ratio of the hole pattern is 0.1 to 1.

9. The gap-filling method of claim 1, wherein the process gas comprises a silicon source gas including at least one of a Si_{X}H_{Y} based silicon precursor, an organic silicon precursor compound, an alkyl silane and an amino silane.

10. The gap-filling method of claim 1, wherein the process gas comprises a nitrogen-including gas including at least one of nitrogen (N₂) gas, nitrogen dioxide (NO₂) gas, nitrous oxide (N₂O) gas, nitrous monoxide (NO) gas, ammonia (NH₃) gas and amine (R—NH₂) gas.

11. A method of manufacturing a semiconductor device, the method comprising:
preparing a substrate with a trench;
forming a first layer under a pulse wave plasma atmosphere, to fill the trench;
forming a second layer on the first layer under a continuous wave plasma atmosphere, thereby applying an overburden to the first layer; and
planarizing the first layer and the second layer using a chemical mechanical polishing, to form a gap-filled layer in the trench.

12. The method of claim 11, wherein at least one of the first layer and second layer includes a silicon nitride layer.

13. The method of claim 11, wherein the pulse wave plasma atmosphere and the continuous wave plasma atmosphere are formed by a VHF (very high frequency) power.

14. The method of claim 11, wherein the first and second layers is formed by a PECVD (plasma enhanced chemical vapor deposition).
